(19) United States
(12) Patent Application Publication
(10) Pub. No.: US 2010/0078320 A1
(43) Pub. Date: Apr. 1, 2010

(54) MICROWAVE PLASMA CONTAINMENT SHIELD SHAPING

(75) Inventor: Michael W. STOWELL, Loveland, CO (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/238,664

(22) Filed: Sep. 26, 2008

(51) Int. Cl. C23C 14/34

(52) U.S. Cl. 204/298.07; 204/192.12

(57) ABSTRACT

The present invention provides microwave systems and methods for achieving better control of process and film properties by optimizing plasma containment shield shaping around an antenna. By using a containment shield, plasma generated by microwave may become more homogeneous, and the pressure inside a processing chamber may be reduced. By optimizing the shape of the containment shield, the lifetime of metastable radical species may be increased. One aspect of extending the lifetime of metastable radical species is to allow better control of chemical reaction and thus help achieve the desired film properties. For an array of antennas, the containment shield comprises a dielectric coated metal base with dividers between the antennas. The divider comprises a dielectric material or a mixture of a dielectric layer and a dielectric coated metal layer, and allows coupling among the antennas. Such a dielectric coated metal containment shield may be easier to be manufactured at lower cost than a containment shield comprising only dielectric material such as quartz.

### BACKGROUND OF THE INVENTION

For thin film deposition, it is often desirable to have a high deposition rate to form coatings on large substrates, and flexibility to control film properties. Higher deposition rate may be achieved by increasing plasma density or lowering the chamber pressure. For plasma etching, higher etching rate may sometimes be helpful for shortening processing cycle time. A high plasma density source is often desirable.

In chemical vapor deposition (CVD), a film is formed by chemical reaction near the surface of a substrate. Typically, reactive gases are introduced into a processing chamber. The reactive gases may decompose from heat to form plasma. Then, chemical reaction may occur on the surface of a substrate to form a film over the substrate. Volatile byproducts may be produced and transported away from the processing chamber. Examples of common CVD technologies include thermal CVD, low pressure CVD (LPCVD), plasma-enhanced CVD (PECVD), microwave plasma-assisted CVD, atmospheric pressure CVD, and the like. LPCVD uses thermal energy for reaction activation. The chamber pressure ranges from 0.1 to 1 torr, where temperature may be controlled to be around 600-900° C. by using multiple heaters. PECVD uses radio frequency (RF) plasma to transfer energy into the reactive gases and form radicals. This process allows a lower temperature than does LPCVD.

Another technique for increasing plasma density is to use a microwave frequency source. Microwave plasma-assisted CVD (MPCVD) inputs microwave power into the reactive gases at a microwave frequency, for example, commonly at 2.45 GHz, which is much higher than the RF frequency of 13.56 MHz. It is well known that at low frequencies, electromagnetic waves do not propagate in a plasma, but are instead reflected. However, at high frequencies such as at typical microwave frequencies, electromagnetic waves effectively allow direct heating of plasma electrons. As the microwaves input energy into the plasma, collisions can occur to ionize the plasma so that higher plasma density can be achieved. Typically, horns are used to inject the microwaves or a small stub antenna is placed in the vacuum chamber adjacent to the sputtering cathode for inputting the microwaves into the chamber. However, this technique does not provide a homogeneous assist to enhance plasma generation. It also does not provide enough plasma density to sustain its own discharge without the assistance of the sputtering cathode. Additionally, scale up of such systems for large area deposition is limited to a length on the order of 1 meter or less due to non-linearity.

There is still a remaining need in the art to provide systems and methods for reducing chamber pressure and increasing the effectiveness and ability to control desired metastable species and densities during plasma processing. There is also a need for improving plasma homogeneity to deposit uniform films on a substrate of a large area. There is also a further need for making large-scale manufacturing possible at reasonable cost.

### BRIEF SUMMARY OF THE INVENTION

Embodiments of the present invention provide microwave systems and methods for achieving better control of process and film properties by optimizing plasma containment shield shaping around an antenna. By using a containment shield, plasma generated by microwaves may become more homogeneous, and the pressure inside a processing chamber may be reduced. By optimizing the containment shield shaping, the lifetime of metastable radical species may be increased. One aspect of extending the lifetime of metastable radical species is to allow better control of chemical reactions and thus help achieve the desired film properties. For an array of antennas, the containment shield comprises a dielectric coated metal base with dividers between the antennas. The divider comprises a dielectric material or a mixture of a dielectric layer and a dielectric coated metal layer, and allows coupling among the antennas. A containment shield comprising dielectric coated metal may be easier for large-scale manufacturing at lower cost than a containment shield comprising only dielectric material such as quartz.

In one set of embodiments, a system comprises a processing chamber, a substrate supporting member for holding a substrate inside the processing chamber, an antenna disposed inside the processing chamber for radiating microwaves, a dielectric coated metal containment shield partially surrounding the antenna, a carrier gas line for providing a flow of sputtering agents, a feedstock line for providing a flow of reactive gases, and an aperture proximate the bottom of the dielectric coated containment shield to allow radical species to escape from the containment shield toward the substrate. The carrier gas line is located inside the containment shield, while the feedstock gas line is located outside the containment shield and proximate the substrate. The antenna comprises a metallic waveguide for converting an electromagnetic wave into a surface wave and a dielectric tube surrounding the metallic waveguide and being substantially coaxial with the metallic waveguide. The containment shield comprises a dielectric coated metal such as aluminum or steel, and may be shaped to have a cross section in the form of a triangle, a circle, or a square, and the like. The dielectric coating may comprise among others, Al₂O₃. A differential pressure may be present in an internal pressure and an external pressure of the containment shield. The internal pressure inside the containment shield may be higher than the external pressure outside the containment shield or chamber pressure such that lower chamber pressure may be achieved, while higher internal pressure allows generation of higher radical density inside the containment shield.

In another set of embodiments, a containment shield partially surrounds an array of antennas with dividers among the antennas. The containment shield comprises a dielectric coated metal base with dividers connected to the metal base. The dividers comprise dielectric material or a mixture of a dielectric layer and a dielectric coated metal layer. An electric potential of the dielectric layer may be different from an electric potential of the dielectric coated metal layer or metal base. The electric field near the dividers may further enhance ionization.

The potential areas of application by the present invention include solar cells (e.g. deposition of amorphous and microcrystalline photovoltaic layers with band gap controllability and increased deposition rates); plasma display devices (e.g. deposition of dielectric layers with energy savings and lower manufacturing cost); scratch resistant coatings (e.g. thin layers of organic and inorganic materials on polycarbonate for UV absorption and scratch resistance); advanced chip-packaging plasma cleaning and pretreatment (e.g. providing small static charge buildup and limiting UV radiation damage); semiconductors, alignment layers, barrier films, optical films, diamond-like carbon and pure-diamond films, where improved barriers and scratch resistance can be achieved by using the present invention; atmospheric etching and coatings; biological agent cleaning; and microwave drying products.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings.

### BRIEF DESCRIPTION OF THE DRAWINGS

FIG. 1 shows a simplified microwave plasma deposition and etch system.

FIG. 2 shows an exemplary simplified deposition system with a generally circular cross section of a containment shield surrounding an antenna.

FIG. 3 shows an exemplary simplified deposition system with a generally triangular cross section of a containment shield surrounding an antenna.

FIG. 4 shows an exemplary simplified deposition system with a generally square cross section of a containment shield surrounding an antenna.

FIG. 5 shows an exemplary array with a containment shield surrounding two antennas with a divider A between the two antennas.

FIG. 6 shows an exemplary array with a containment shield surrounding three antennas with a divider B between the two antennas.

FIG. 7A shows an exemplary simplified deposition system with a generally circular cross section of a containment shield surrounding two antennas.

FIG. 7B shows an exemplary simplified deposition system with a generally triangular cross section of a containment shield surrounding two antennas.

FIG. 8 is a flow chart for illustrating simplified deposition steps for forming a film on a substrate.

FIG. 9 illustrates the effect of pulsing frequency on the light signal from plasma.

FIG. 10A provides a simplified schematic of a planar plasma source consisting of 4 coaxial microwave linear sources.

FIG. 10B provides an optical image of a planar microwave source consisting of 8 parallel coaxial microwave plasma sources.

FIG. 11 shows the homogeneity of a coaxial microwave plasma linear source.

FIG. 12 is a graph demonstrating the saturation of continuous microwave plasma density versus microwave power.

FIG. 13 is a graph revealing the improved plasma efficiency in pulsing microwave power compared to continuous microwave power.

FIG. 14 is an optical image of two antennas inside a containment shield.

### DETAILED DESCRIPTION OF THE INVENTION

### 1. Overview of Microwave-Assisted Deposition

Microwave plasma has been developed to achieve higher plasma densities (e.g. ˜10¹² ions/cm³) and higher deposition rates, as a result of improved power coupling and absorption at 2.45 GHz when compared to a typical radio frequency (RF) coupled plasma sources at 13.56 MHz. One drawback of using RF plasma is that a large portion of the input power is dropped across the plasma sheath (dark space). By using microwave plasma, a narrow plasma sheath is formed and more power can be absorbed by the plasma for creation of radical and ion species, which increases the plasma density and obtains a narrow energy distribution by reducing collision broadening of the ion energy distribution.

Microwave plasma also has other advantages, such as lower ion energies with a narrow energy distribution. For instance, microwave plasma may have low ion energy of 0.1-25 eV, which leads to lower damage when compared to processes that uses RF plasma. In contrast, standard planar discharge would result in high ion energy of 100 eV with a broader distribution in ion energy, which would lead to higher damage, as the ion energy exceeds the binding energy for most materials of interest. This ultimately inhibits the formation of high-quality crystalline thin films through the introduction of intrinsic defects. With low ion energy and narrow energy distribution, microwave plasma helps in surface modification and improves coating properties.

In addition, a lower substrate temperature (e.g. lower than 200° C., for instance at 100° C.) is achieved as a result of increased plasma density at lower ion energy with narrow energy distribution. Such a lower temperature allows better microcrystalline growth in kinetically limited conditions. Also, standard planar discharge without magnetron normally requires a pressure greater than about 50 mtorr to maintain self-sustained discharge, as plasma becomes unstable at pressures lower than about 50 mtorr. The microwave plasma technology described herein allows the pressure to range from about 10⁻⁶ torr to 1 atmospheric pressure. The processing windows such as temperature and pressure are therefore extended by using a microwave source.

In the past, one drawback associated with microwave source technology in the vacuum coating industry was the difficulty in maintaining homogeneity during the scale up from small wafer processing to very large area processing. Microwave reactor designs in accordance with embodiments of the invention address these problems. Arrays of coaxial plasma linear sources have been developed to deposit substantially uniform coatings of ultra large area (greater than 1 m²) at high deposition rate to form dense and thick films (e.g. 5-10 μm thick).

An advanced pulsing technique has been developed to control the microwave power for generating plasma, and thus to control the plasma density and plasma temperature. This advanced pulsing technique may reduce the thermal load disposed over the substrate, as the average power may remain low. This feature is relevant when the substrate has a low melting point or a low glass transition temperature, such as in the case of a polymer substrate. The advanced pulsing technique allows high power pulsing into plasma with off times in between pulses, which reduces the need for continuous heating of the substrate. Another aspect of the pulsing technique is significant improvement in plasma efficiency compared to continuous microwave power.

2. Lower Chamber Pressure with Microwave Assist

For planar discharge, a DC voltage may be applied to a target to make the target a cathode and the substrate an anode. The DC voltage helps accelerate free electrons. The free electrons collide with sputtering agents such as argon (Ar) atoms from argon gas to cause excitation and ionization of Ar atoms. The excitation of Ar results in gas glow. The ionization of Ar generates Ar⁺ and secondary electrons. The secondary electrons repeat the excitation and ionization process to sustain the plasma discharge.

Near the cathode, positive charges build up as the electrons move much faster than ions due to their smaller mass. Therefore, fewer electrons collide with Ar so that fewer collisions with the high energy electrons result in mostly ionization rather than excitation. A Crookes dark space is formed near the cathode. Positive ions entering the dark space are accelerated toward the cathode or target and bombard the target so that atoms are knocked out from the target and then transported to the substrate and also secondary electrons are generated to sustain the plasma discharge. If the distance between cathode to anode is less than the dark space, few excitations occur and discharge can not be sustained. On the other hand, if the Ar pressure in a chamber is too low, there would be a larger electron mean free path such that secondary electrons would reach anode before colliding with Ar atoms. In this case, discharge also can not be sustained. Therefore, a condition for sustaining the plasma is

L*P>0.5 (cm-torr)

where L is the electrode spacing and P is the chamber pressure. For instance, if a spacing between the target and the substrate is 10 cm, P should be greater than 50 mtorr.

The mean free path λ of an atom in a gas is given by:

λ(cm)˜5×10⁻³/P (torr)

If P is 50 mtorr, λis about 0.1 cm. This means that sputtered atoms or ions typically have hundreds of collisions before reaching the substrate. This reduces the deposition rate significantly. In fact, the sputtering rate R is inversely proportional to the chamber pressure and the spacing between target and substrate. Therefore, lowering required chamber pressure for sustaining discharge increases deposition rate.

With a secondary microwave source near the sputtering cathode, the sputtering system allows the cathode to run at a lower pressure, lower voltage and possibly higher deposition rate. By decreasing operational voltage, atoms or ions have lower energy so that damage to the substrate is reduced. With the high plasma density and lower energy plasma from microwave assist, high deposition rate can be achieved along with lower damage to the substrate.

### 3. Plasma Containment Shield and Shaping

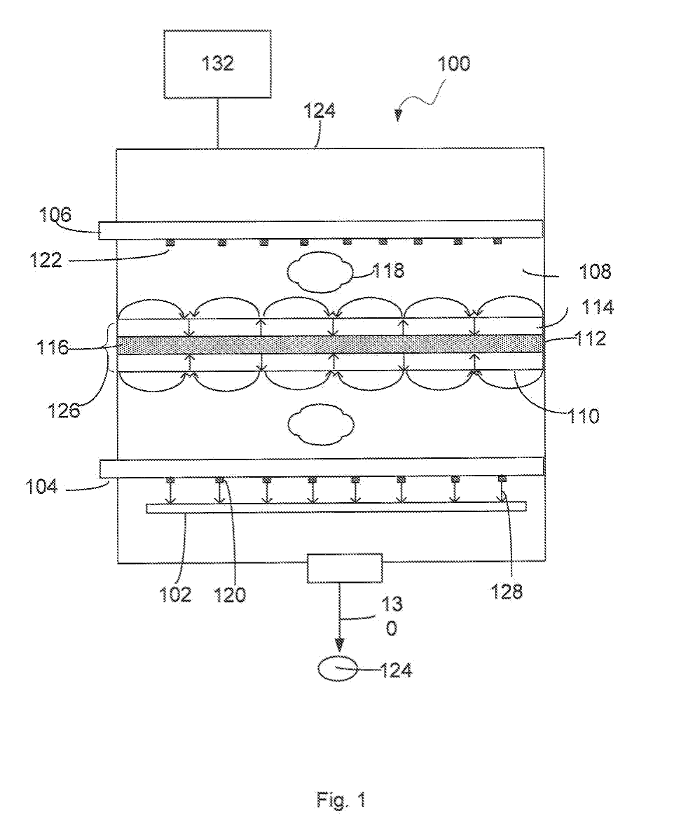

FIG. 1 shows a simplified diagram of a coaxial microwave-assisted chemical vapor deposition (CVD) system 100 without containment shield. Multiple-step processes can also be performed on a single substrate or wafer without removing the substrate from the chamber. The major components of the system include, among others, a processing chamber 124 that receives precursors from feedstock gas line 104 and carrier gas line 106, a vacuum system 122, a coaxial microwave line source 126, a substrate 102, and a controller 132.

The coaxial microwave line source 126 includes, among others, an antenna 112, a microwave source 116 which inputs the microwave into the antenna 112, an outer envelope surrounding the antenna 112 made of dielectric material (e.g. quartz), which serves as a barrier between the vacuum pressure 108 and atmospheric pressure 114 inside the dielectric layer 110. The atmospheric pressure is needed for cooling the antenna 112. Electromagnetic waves are radiated into the chamber 124 through the dielectric layer 110 and plasma 118 may be formed over the surface of the dielectric material such as quartz. In a specific embodiment, the coaxial microwave line source 126 may be about 1 m long. An array of the line sources 126 may sometimes be used in the processing chamber 124.

The feedstock gas line 104 may be located below the coaxial microwave line source 126 and above the substrate 102 which is near the bottom of the processing chamber 124. The carrier gas line may be located above the coaxial microwave source 126 and near the top of the processing chamber 124. Through the feedstock gas line 104 and perforated holes 120, the precursor gases and carrier gases flow into the processing chamber 124. The precursor gases are vented toward the substrate 102 (as indicated by arrows 128), where they may be uniformly distributed radically across the substrate surface, typically in a laminar flow. After deposition is completed, exhaust gases exit the processing chamber 124 by using vacuum pump 122 through exhaust line 130.

The controller 132 controls activities and operating parameters of the deposition system, such as the timing, mixture of gases, chamber pressure, chamber temperature, pulse modulation, microwave power levels, and other parameters of a particular process.

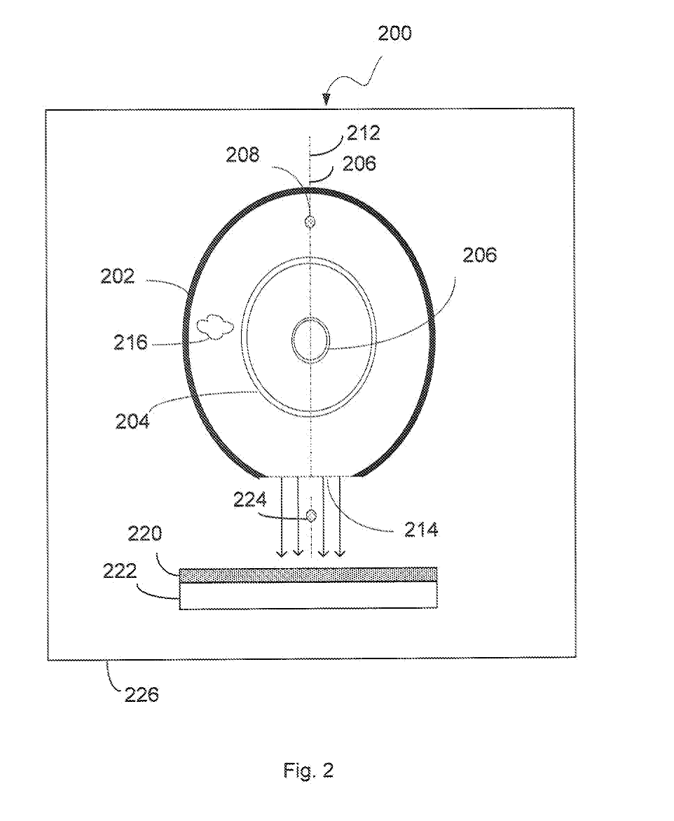

FIG. 2 shows an exemplary simplified deposition system 200 with a generally circular cross section of containment shield 202 partially surrounding an antenna. The antenna comprises a waveguide 206 and a dielectric tube 204 as a pressure isolation barrier. Air or nitrogen is filled in the space between the dielectric tube 204 and waveguide 206 for cooling the antenna. The first pressure inside the dielectric tube 204 may be one atmospheric pressure. The circular containment shield 202 is outside the dielectric tube 204 for containing plasma 216 that is formed from sputtering agents coming from a carrier gas line 208 located on a centerline 212. The plasma 216 comes through an aperture 214 near the bottom of the containment shield 202 to collide with reactive precursors from a feedstock gas line 224. Radical species generated by the plasma 216 disassociate the reactive precursors to form a film on a substrate 220 that is held by a substrate supporting member 222. The second pressure inside the containment shield 202 may be higher than the third pressure inside a processing chamber 226. The dielectric tube may comprise a quartz to form a pressure isolation barrier and still allow microwaves to leak through.

A feedstock gas line 224 is normally located outside the containment shield and proximate the substrate to be coated as shown in FIG. 2. The reason for this is that radical density may be so high that some of the radicals may deposit over the inner wall of the containment shield 202. The feedstock gas contains one or more of the atoms or molecules to produce desired dielectric coatings such as SiO₂, where a silicon containing gas, for example, hexamethyldisiloxane (HMDSO), should always be in the feedstock gas line. The position of the feedstock gas line may be adjusted to control the film chemistry. There are also exceptional cases where a reactive gas may be included among the carrier gases, such as ammonia that may be used to form nitride.

The containment shield 202 may comprise a dielectric material, such as Al₂O₃ or quartz, or a dielectric coated metal. The dielectric coated metal shield is easier to be formed to any desired shape and manufactured at reasonable cost than a quartz shield.

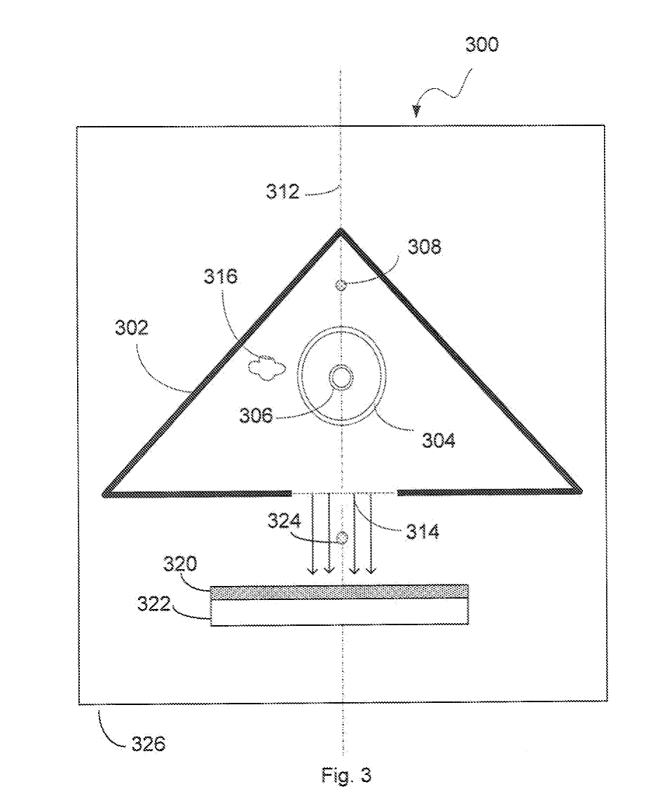

FIG. 3 shows an exemplary simplified deposition system 300 with a generally triangular cross section of containment shield 302 partially surrounding an antenna. The antenna comprises a waveguide 306 and a dielectric tube 304 as a pressure isolation barrier. Air or nitrogen is filled in the space between the dielectric tube 304 and waveguide 306 for cooling the antenna. The first pressure inside the dielectric tube 304 may be one atmospheric pressure. The triangular containment shield 302 is outside the dielectric tube 304 for containing plasma 316 that is formed from sputtering agents coming from a carrier gas line 308 located on a centerline 312. The plasma 316 comes through an aperture 314 near the bottom of the containment shield 302 to collide with reactive precursors from a feedstock gas line 324. Radical species generated by the plasma 316 disassociate the reactive precursors to form a film on a substrate 320 that is held by a substrate supporting member 322. The second pressure inside the containment shield 302 may be higher than the third pressure inside a processing chamber 326. The dielectric tube may comprise a quartz to form a pressure isolation barrier and still allow microwaves to leak through.

The inventors performed modeling for the triangular shield. The inventors found that the shield shape may be configured to increase lifetime of metastable specifies, since at least some of the gases from the carrier gas line take longer time to go through the aperture 314 because of the triangular shape of the containment shield. For example, with the triangular shield, the lifetime increases from approximately 1 μswithout the shield to 3 μs. This increased lifetime allows chemical reactions of reactive precursors to be controlled and thus for the properties of formed films to be controlled.

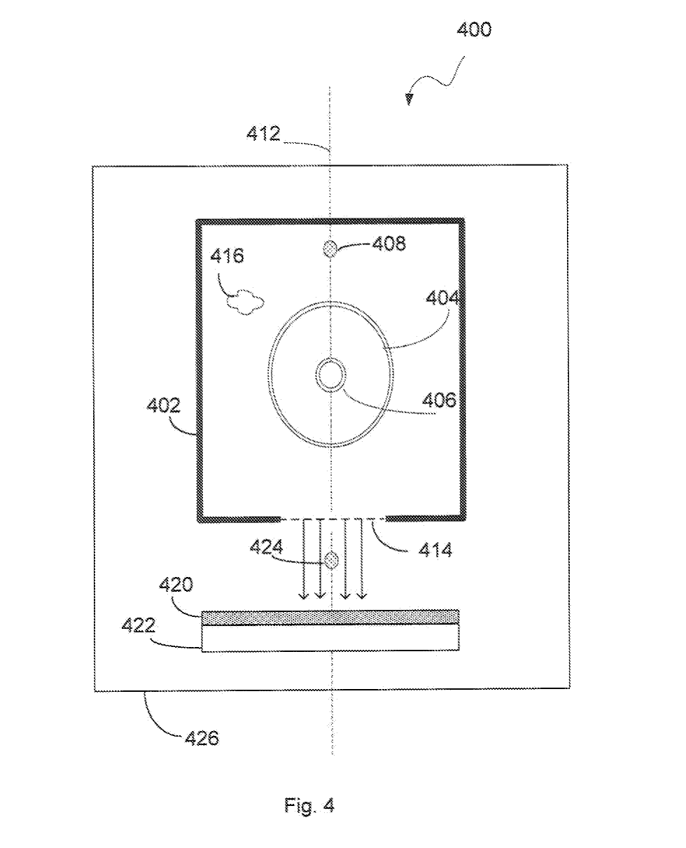

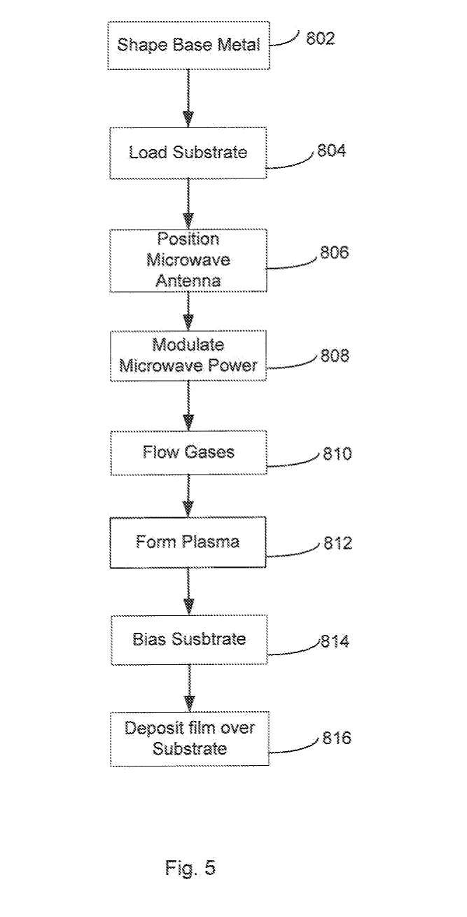

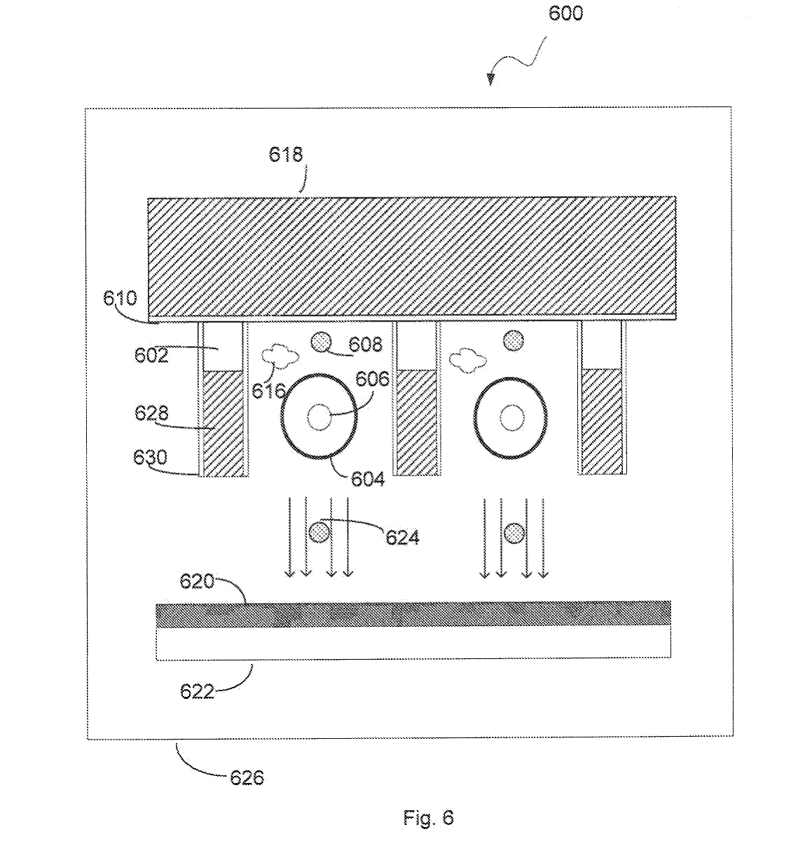

FIG. 4 shows an exemplary simplified deposition system 400 with a generally square cross section of containment shield 402 partially surrounding an antenna. The antenna comprises a waveguide 406 and a dielectric tube 404 as a pressure isolation barrier. Air or nitrogen is filled in the space between the dielectric tube 404 and waveguide 406 for cooling the antenna. The first pressure inside the dielectric tube 404 may be one atmospheric pressure. The square containment shield 402 is outside the dielectric tube 404 for containing plasma 416 that is formed from sputtering agents coming from a carrier gas line 408 located on a centerline 412. The plasma 416 comes through an aperture 414 near the bottom of the containment shield 402 to collide with reactive precursors from a feedstock gas line 424. Radical species generated by the plasma 416 disassociate the reactive precursors to form a film on a substrate 420 that is held by a substrate supporting member 422. The second pressure inside the containment shield 402 may be higher than the third pressure inside a processing chamber 426. The dielectric tube may comprise quartz to form a pressure isolation barrier and still allow microwaves to leak through. This shield shape is used in an exemplary array with containment shield surrounding two antennas with a divider between two antennas (see FIGS. 5 and 6).

FIG. 5 shows an exemplary array 500 with containment shield partially surrounding two antennas with a divider A between the antennas inside a processing chamber 526. The containment shield comprises a dielectric layer 510 coated metal base 518, and a dielectric divider 502 between two antennas. The divider is in contact with the dielectric coated metal base 518. The antenna comprises a conductive waveguide 506 and a dielectric tube 504 surrounding the waveguide 506. A carrier gas line 508 is located above the antenna and inside the containment shield. Plasma 516 is formed from the carrier gas provided by the carrier gas line. A feedstock gas line 524 is located outside the containment shield and proximate a substrate 520 that is supported by a substrate supporting member 522.

FIG. 6 shows an exemplary array 600 with containment shield partially surrounding two antennas with a divider A between the antennas inside a processing chamber 626. The containment shield comprises a dielectric layer 610 coated metal base 618 and a divider between two antennas. The divider comprises a mixture of a dielectric layer 602 and a dielectric layer 610 coated metal layer 628 and is in contact with the dielectric coated metal base 618. The antenna comprises a conductive waveguide 606 and a dielectric tube 604 surrounding the waveguide 606. A carrier gas line 608 is located above the antenna and inside the containment shield. Plasma 616 is formed from the carrier gas provided by the carrier gas line. A feedstock gas line 624 is located outside the containment shield and proximate a substrate 620 that is supported by a substrate supporting member 622.

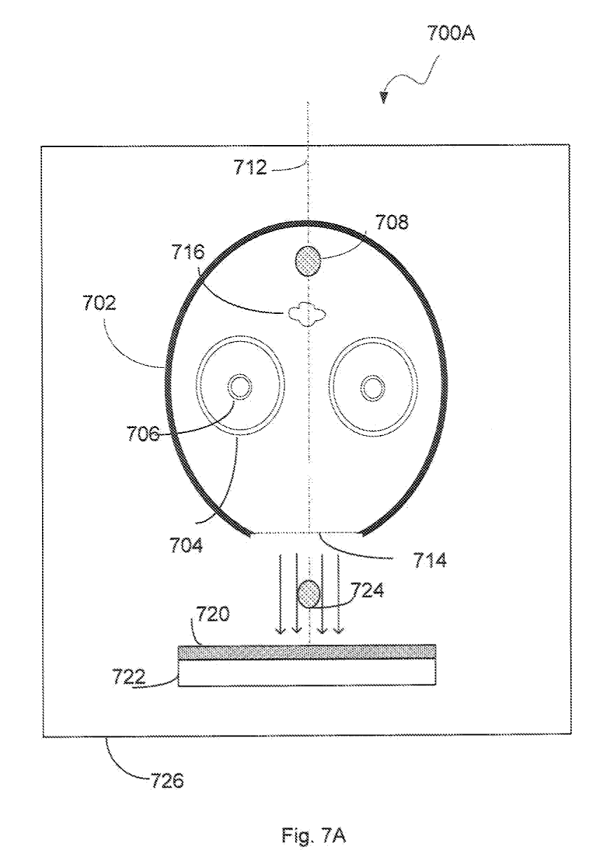

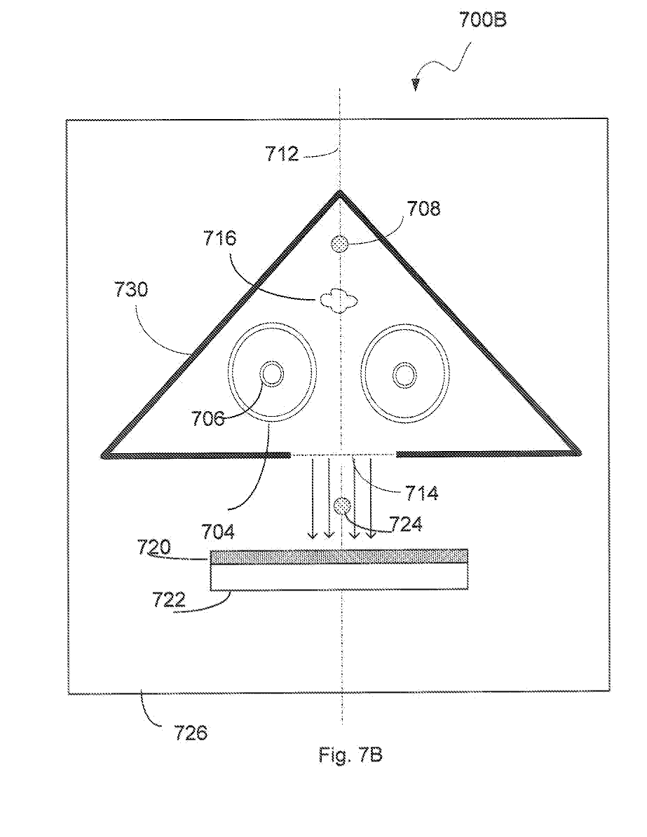

FIG. 7A shows an exemplary simplified deposition system 700A with a circular containment shield 702 surrounding two antennas. This system is similar to that shown in FIG. 2, except two antennas are provided inside the circular containment shield 702. Each antenna comprises a waveguide 706 and a dielectric tube 704 as a pressure isolation barrier. The two antennas are symmetrically positioned relative to the centerline 712. Air or nitrogen is filled in the space between the dielectric tube 704 and waveguide 706 for cooling the antenna. The first pressure inside the dielectric tube 704 may be one atmospheric pressure. The circular containment shield 702 is outside the dielectric tube 704 for containing plasma 716 that is formed from sputtering agents coming from a carrier gas line 708 located on a centerline 712. The plasma 716 comes through an aperture 714 near the bottom of the containment shield 702 to collide with reactive precursors from a feedstock gas line 724. Radical species generated by the plasma 716 disassociate the reactive precursors to form a film on a substrate 720 that is held by a substrate supporting member 722. The second pressure inside the containment shield 702 may be higher than the third pressure inside a processing chamber 726. The dielectric tube may comprise quartz to form a pressure isolation barrier and still allow microwaves to leak through.

FIG. 7B shows an exemplary simplified deposition system 700B with a triangular containment shield 730 surrounding two antennas. This system is very similar to the system 700A except for the inclusion of the shield 730.

A few aspects of using a plasma containment shield around an antenna or a plurality of antennas are discussed here. First, a pressure difference may be present between the internal pressure of the containment shield and external pressure of the containment shield, with the internal pressure being higher than the external pressure. This allows more processing flexibility than without using the containment shield. With increased pressure inside the containment shield, plasma species or radicals may have more collisions and thus higher radical density. With lower pressure outside the containment shield, this means that the chamber pressure may be lower. As a result of lower chamber pressure, the mean free path increases for plasma species or radicals and thus deposition rate is increased.

Furthermore, the plasma containment shield may help increase radical density and form homogeneous plasma, as the shield helps increase the collisions among the radicals by confining the radicals within the containment shield without losing the radical species. As a result of using the plasma containment shield, radical density is increased and homogeneity is improved, particularly in radical direction.

In addition, by using a containment shield, the volume of the gas inside the plasma containment shield may be more fully ionized and thus may produce more radicals so that ionization efficiency may be improved. For example, the inventors performed experimental tests to demonstrate that the ionization efficiency may be improved from 65% to 95% by using a plasma containment shield.

Additional improvement in processing control can be achieved by optimizing the shield shaping. One aspect of the improvement is to increase the lifetime of radical species by shaping the shield. For illustration purpose, FIG. 3 shows a generally triangular cross section of the shield. The inventor demonstrated that this triangular shield may help increase the lifetime of the radicals from 1 μs to 3 μs. This increase in lifetime for radicals allows the chemical reaction of radicals to be tuned and thus to affect the film properties. By using a dielectric coated metal containment shield, it is easier to manufacture the containment shield for large-scale applications at reasonable cost compared to fabrication of a quartz shield of a complicated geometry.

When using an array of antennas as shown in FIGS. 5 and 6, decoupling between the antennas by a metal divider is normally desired for reducing the interference between the antennas in order to generate homogeneous plasma. However, in embodiments of the present invention, coupling is allowed through the divider, as the divider may be made of a dielectric material or partially of a dielectric material. By using a plasma containment shield, this coupling effect between the antennas is reduced, as the containment shield helps form homogeneous plasma inside the plasma containment shield. This coupling feature between the antennas is therefore a relevant distinction from structures in which the divider is made of metal.

Another aspect of the array is that there may be an electric potential between the dielectric divider and the dielectric coated metal base. Referring to FIG. 6 again, the divider may comprise a mixture of a dielectric layer and a dielectric coated metal layer. There may be an electric potential between the dielectric layer and the dielectric coated metal layer or metal base. This electrical potential between the different layers of the divider may further enhance ionization nearby.

### 4. Exemplary Deposition Process

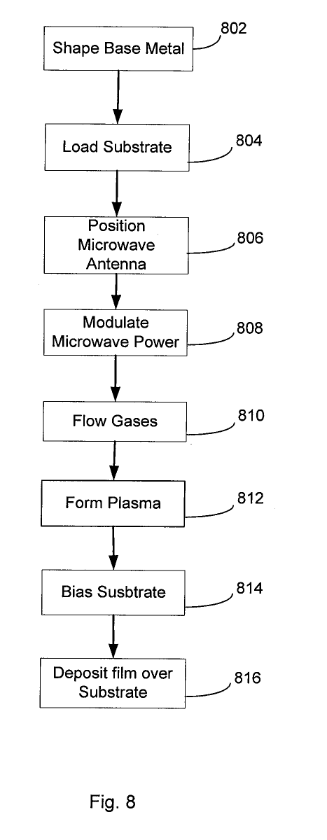

For purposes of illustration, FIG. 8 provides a flow diagram of a process that may be used to form a film on a substrate. The process begins with shaping a base metal into a desired form for a containment shield at block 802. The metal base is then applied with a dielectric coating to form a containment shield. In a special case of an array of antennas, the containment shield comprises a metal base coated with a dielectric material and a number of dividers to physically separate the antennas. Next, a substrate is loaded into a processing chamber as indicated at block 804. A microwave antenna is moved to a desired position inside the containment shield at block 806. A microwave is generated by an antenna at block 808 and modulated, for instance, by a power supply using a pulsing power or a continuous power. Film deposition is initiated by flowing gases, such as sputtering agents or reactive precursors at block 810.

For deposition of SiO₂, such precursor gases may include a silicon-containing precursor such as hexamthyldisiloxane (HMDSO) and oxidizing precursor such as O₂. For deposition of SiOₓN_{y}, such precursor gases may include a silicon-containing precursor such as hexmethyldislanzane (HMDS), a nitrogen-containing precursor such as ammonia (NH₃), and an oxidizing precursor. For deposition of ZnO, such precursor gases may include a zinc-containing precursor such as diethylzinc (DEZ), and an oxidizing precursor such as oxygen (O₂), ozone (O₃) or mixtures thereof. The reactive precursors may flow through separate lines to prevent them from reacting prematurely before reaching the substrate. Alternatively, the reactive precursors may be mixed to flow through the same line.

The carrier gases may act as a sputtering agent. For example, the carrier gas may be provided with a flow of H₂ or with a flow of inert gas, including a flow of He or even a flow of a heavier inert gas such as Ar. The level of sputtering provided by the different carrier gases is inversely related to their atomic mass. Flow may sometimes be provided of multiple gases, such as by providing both a flow of H₂ and a flow of He, which mix in the processing chamber. Alternatively, multiple gases may sometimes be used to provide the carrier gases, such as when a flow of mixed H₂/He is provided into the processing chamber.

As indicated at block 812, a plasma is formed from the gases by microwave at a frequency ranging from 1 GHz to 10 GHz, for example, commonly at 2.45 GHz (a wavelength of 12.24 cm). In addition, a higher frequency of 5.8 GHz is often used when power requirement is not as critical. The benefit of using a higher frequency source is that it has smaller size (about half size) of the lower frequency source of 2.45 GHz. In some embodiments, the plasma may be a high-density plasma having an ion density that exceeds 10¹² ions/cm³.

Also, in some instances the deposition characteristics may be affected by applying an electrical bias to the substrate at block 814. Application of such a bias causes the ionic species of the plasma to be attracted to the substrate, sometimes resulting in increased sputtering. The environment within the processing chamber may also be regulated in other ways in some embodiments, such as controlling the pressure within the processing chamber, controlling the flow rates of the precursor gases and where they enter the processing chamber, controlling the power used in generating the plasma, controlling the power used in biasing the substrate and the like. Under the conditions defined for processing a particular substrate, material is thus deposited over the substrate as indicated at block 816.

The inventor has demonstrated an increase of deposition rate of approximately 3 times using pulsing microwaves in CVD. A SiO₂ film of about 5 μm thick and an area of approximately 800 mm by 200 mm was deposited on a substrate of about 1 m². The substrate was statically heated to about 280° C. The deposition time was only 5 minutes such that the deposition rate was roughly 1 μm/min. The SiO₂ film yielded excellent optical transmittance and also had low contents of undesired organic materials.

### 5. Exemplary Planar Microwave Sources and Features

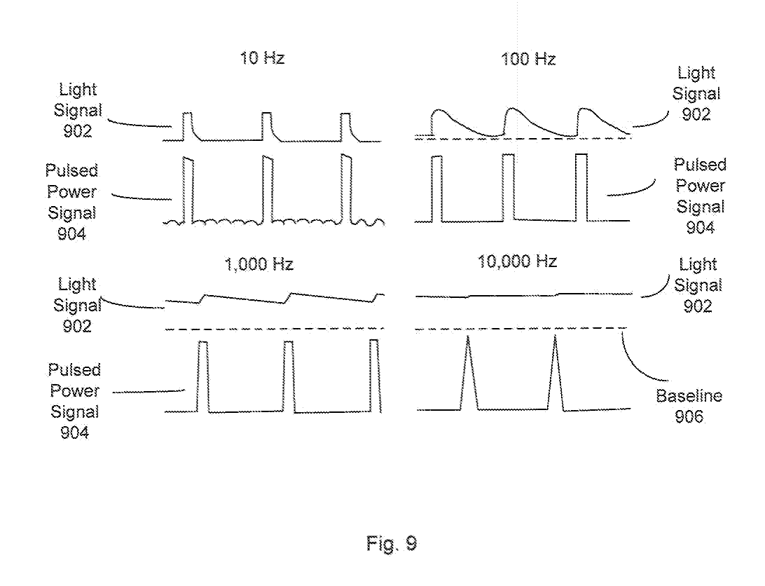

Pulsing frequency may affect the microwave pulsing power into plasma. FIG. 9 shows the frequency effect of the microwave pulsing power 904 on the light signal of plasma 902. The light signal of plasma 902 reflects the average radical concentration. As shown in FIG. 9, at a low pulsing frequency such as 10 Hz, in the event that all radicals are consumed, the light signal from plasma 902 decreases and extinguishes before the next power pulse comes in. As pulsing frequency increases to higher frequency such as 10,000 Hz, the average radical concentration is higher above the baseline 906 and becomes more stable.

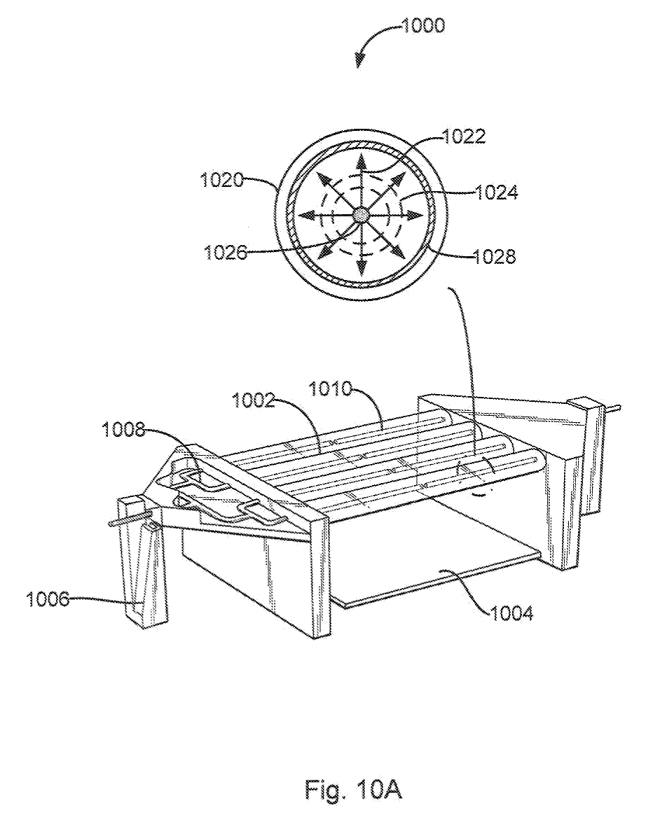

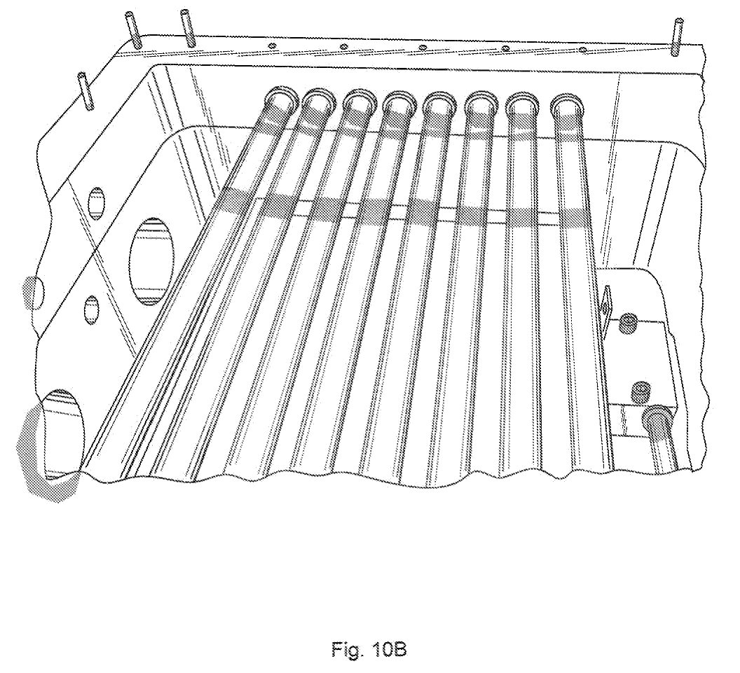

FIG. 10A shows a schematic of a simplified system including a planar coaxial microwave source 1002 comprising 4 coaxial microwave linear sources 1010, a substrate 1004, a cascade coaxial power provider 1008 and an impedance matched rectangular waveguide 1006. In the coaxial microwave linear source 1010, microwave power is radiated into the chamber in a transversal electromagnetic (TEM) wave mode. A tube replacing the outer conductor of the coaxial line is made of dielectric material such as quartz or alumina having high heat resistance and a low dielectric loss, which acts as the interface between the waveguide having atmospheric pressure and the vacuum chamber.

A cross sectional view of the coaxial microwave linear source 1000 illustrates a conductor 1026 for radiating microwaves at a frequency of 2.45 GHz. The radial lines represent an electric field 1022 and the circles represent a magnetic field 1024. The microwaves propagate through the air to the dielectric layer 1028 and then leak through the dielectric layer 1028 to form an outer plasma conductor 1020 outside the dielectric layer 1028. Such a wave sustained near the coaxial microwave linear source is a surface wave. The microwaves propagate along the linear line and go through a high attenuation by converting electromagnetic energy into plasma energy. Another configuration that may be used is without quartz or alumina outside the microwave source (not shown).

FIG. 10B shows an optical image of a planar coaxial microwave source comprising 8 parallel coaxial microwave linear sources. The length of each coaxial microwave linear source may be up to 3 m in some embodiments.

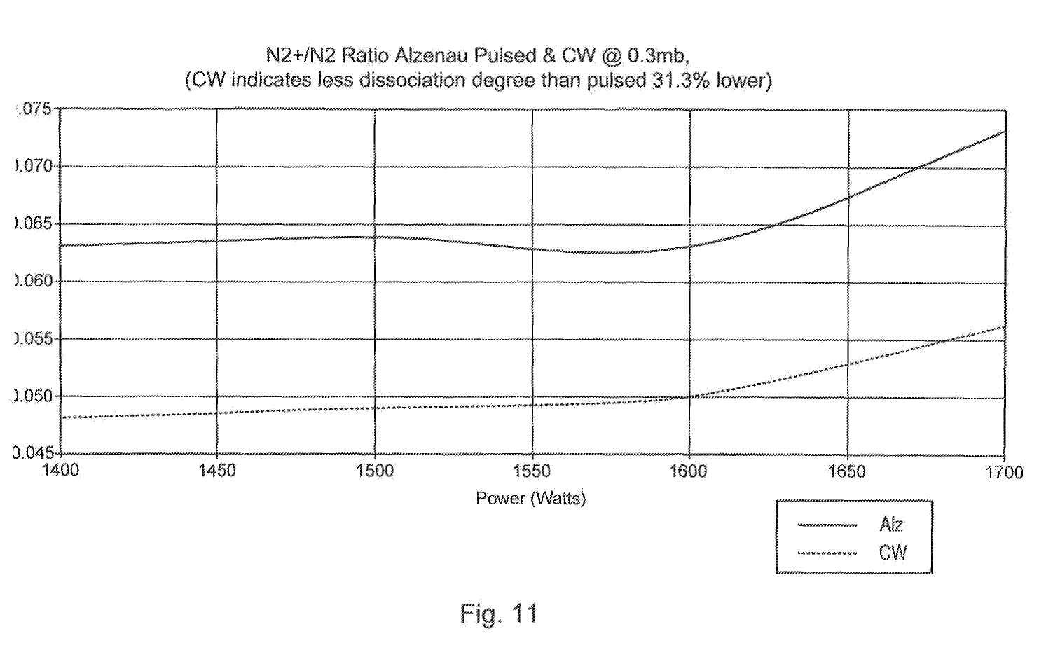

Typically, the microwave plasma linear uniformity is about ±15%. FIG. 11 shows the homogeneity of the coaxial microwave source obtained shown in FIG. 10B. The inventors have performed experiments to demonstrate that approximately ±1.5% of homogeneity over 1 m² can be achieved in dynamic array configuration and 2% over 1 m² in static array configurations. This homogeneity may be further improved to be below ±1% over large areas.

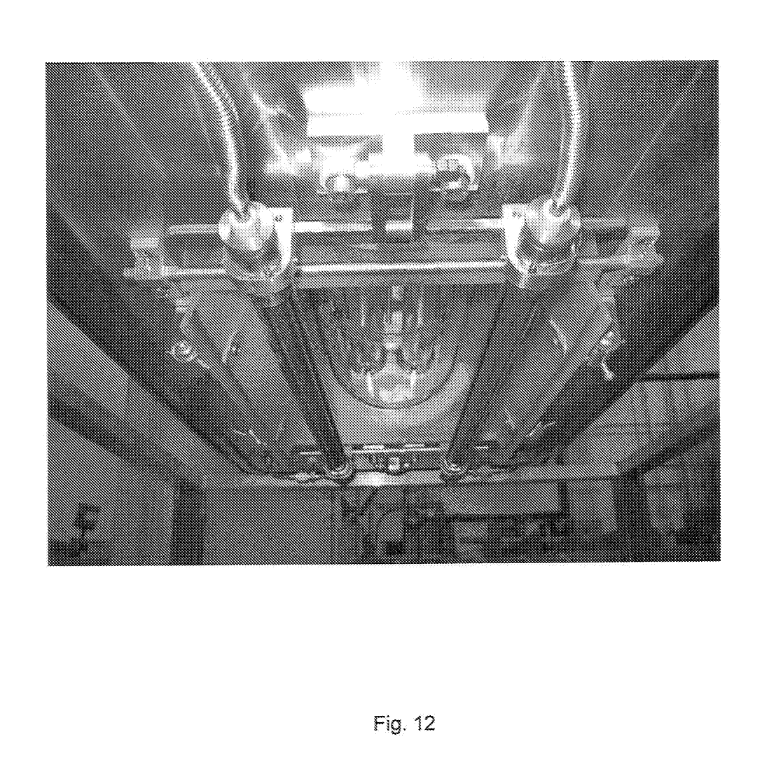

FIG. 12 shows plasma density versus continuous microwave power. Note that when plasma density increases to above 2.2×10¹¹/cm³, the plasma density starts to saturate with increasing microwave power. The reason for this saturation is that the microwave radiation is reflected more once the plasma density becomes dense. Due to the limited power in available microwave sources, microwave plasma linear sources of any substantial length may not achieve optimal plasma conditions, i.e. very dense plasma. Pulsing microwave power allows for much higher peak energy into the antenna than continuous microwaves, such that the optimal plasma condition can be approached.

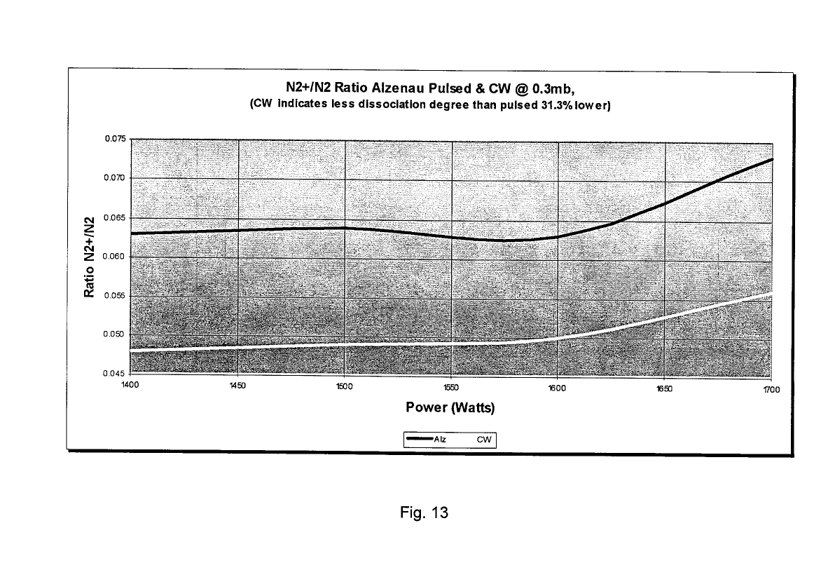

FIG. 13 shows a graph which illustrates the improved plasma efficiency of pulsing microwaves over continuous microwaves for pulsing microwaves that have the same average power as the continuous microwaves. Note that continuous microwaves result in less disassociation as measured by the ratio of nitrogen radical N₂+ over neutral N₂. A 31% increase in plasma efficiency can be achieved by using pulsing microwave power.

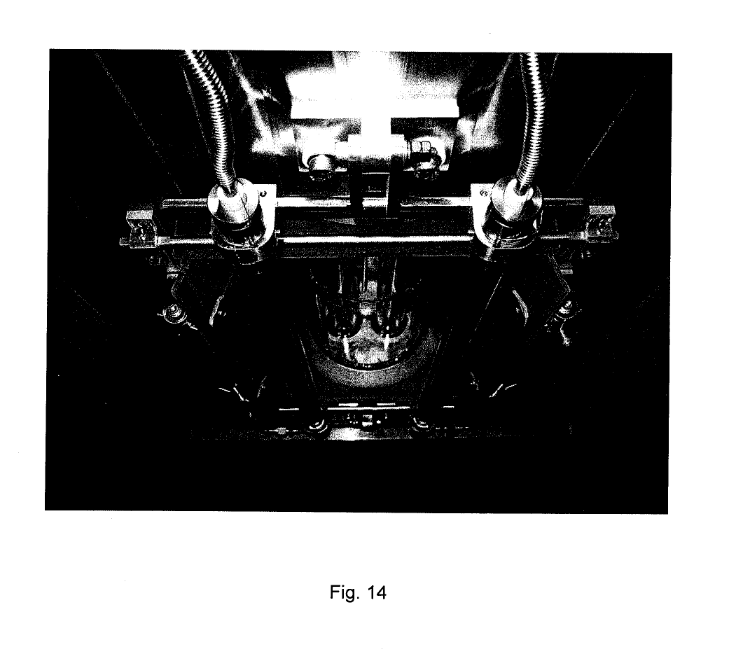

FIG. 14 shows an optical image of a containment shield having two antennas inside.

While the above is a complete description of specific embodiments of the present invention, various modifications, variations and alternatives may be employed. Moreover, other techniques for varying the parameters of deposition could be employed in conjunction with the coaxial microwave plasma source. Examples of the possible variations include but are not limited to variations in shapes and materials for a containment shield, different waveforms for pulsing power applied to the microwave antenna, various positions of the antenna, the microwave source, linear or planar, pulsing power or continuous power to the microwave source, the RF bias condition for the substrate, the temperature of the substrate, the pressure of deposition, and the flow rate of inert gases and the like.

Having described several embodiments, it will be recognized by those skilled in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

What is claimed is:

1. A microwave assisted deposit and etch system comprising:
a processing chamber;
a substrate supporting member disposed inside the processing chamber, the substrate supporting member being configured to hold a substrate;
an antenna disposed inside the processing chamber for radiating microwaves;
a containment shield partially surrounding the antenna;
a carrier gas line for providing a flow of sputtering agents, the carrier gas line being located between the antenna and the containment shield;
a feedstock gas line for providing a flow of precursor gases, the feedstock gas line being located between a bottom of the containment shield and the substrate; and
an aperture for allowing radical species generated from the sputtering agents to escape from the containment shield and collide with the precursor gases, the aperture being located proximate the bottom of the containment shield, wherein the containment shield is shaped to increase the distance for at least some of the radical species to pass from the carrier gas line through the aperture.

2. The microwave assisted deposit and etch system of claim 1, wherein the antenna comprises:
a metallic waveguide for converting an electromagnetic wave into a surface wave and radiating the surface wave in a radial direction;
a dielectric tube, the dielectric tube surrounding the metallic waveguide and being substantially coaxial with the metallic waveguide.

3. The microwave assisted deposit and etch system of claim 2, wherein the dielectric tube comprises quartz.

4. The microwave assisted deposit and etch system of claim 1, wherein a cross-section of the dielectric coated metal containment shield comprises a shape generally corresponding to a triangle, a circle or a square.

5. The microwave assisted deposit and etch system of claim 1, wherein the containment shield comprises a dielectric coated metal.

6. The microwave assisted deposit and etch system of claim 5, wherein the metal comprises aluminum or steel.

7. The microwave assisted deposit and etch system of claim 5, wherein the dielectric comprises Al₂O₃.

8. The microwave assisted deposit and etch system of claim 1, wherein:
a first pressure in the space between the dielectric tube and the metallic waveguide is one atmospheric pressure; and
a second pressure in the space between the antenna and the dielectric coated metal containment shield is less than the first pressure; and
a third pressure outside the plasma containment shield is lower than the second pressure.

9. The microwave assisted deposit and etch system of claim 8, wherein the first pressure ranges between approximately 0.1 mtorr and 1 atmospheric pressure.

10. A microwave assisted deposit and etch system comprising:
a processing chamber;
a substrate supporting member disposed inside the processing chamber, the substrate supporting member being configured to support a substrate;
a first and a second antenna disposed inside the processing chamber for radiating microwaves;
a containment shield comprising a base and a divider being positioned between the first antenna and the second antenna and connected to the base, wherein the divider comprises at least partially of a dielectric material and the containment shield at least partially surrounds the first antenna and the second antenna;
a first carrier gas line providing a flow of sputtering agents, the first carrier gas line being located between the first antenna and the containment shield;
a second carrier gas line providing a flow of sputtering agents, the second carrier gas line being located between the second antenna and the containment shield;
a first and a second feedstock gas line for providing a flow of precursor gases, the first and second feedstock gas lines being located between a bottom of the containment shield and the substrate; and
a first and a second aperture for allowing radical species generated from the sputtering agents to escape from the containment shield and collide with the precursor gases, the first and second apertures being located proximate the bottom of the containment shield.

11. The microwave assisted deposit and etch system of claim 10, wherein the base comprises a dielectric coated metal.

12. The microwave assisted deposit and etch system of claim 10, wherein the divider comprises:
a first layer of dielectric material, the first layer being in contact with the base; and
a second layer of metal disposed over the first layer; wherein a non-overlapping surface of the second layer with the first layer has a dielectric coating.

13. The microwave assisted deposit and etch system of claim 12, wherein an electric potential of the first layer of dielectric material is different from an electric potential of the second layer of metal.

14. The microwave assisted deposit and etch system of claim 11, wherein the metal comprises aluminum or steel.

15. The microwave assisted deposit and etch system of claim 11, wherein the dielectric comprises Al₂O₃.

16. The microwave assisted deposit and etch system of claim 10, wherein the antenna comprises:
a metallic waveguide for converting an electromagnetic wave into a surface wave and radiating the surface wave in a radial direction;
a dielectric tube, the dielectric tube surrounding the metallic waveguide and being substantially coaxial to the metallic waveguide.

17. The microwave assisted deposit and etch system of claim 10, wherein:
a first pressure in the space between the dielectric tube and the metallic waveguide is one atmospheric pressure.
a second pressure in the space between the antenna and the plasma containment shield is lower than the first pressure; and
a third pressure outside the plasma containment shield is lower than the second pressure.

18. The microwave assisted deposit and etch system of claim 10, wherein the second pressure is between approximately 0.1 mtorr and 1 atmospheric pressure

19. A method for microwave assisted deposition and etching, the method comprising:
loading a substrate into a processing chamber;
positioning an antenna inside a containment shield;
modulating microwave power into the antenna;
supplying a carrier gas inside the containment shield and a precursor gas outside the containment shield;
forming a plasma from the carrier gas and the precursor gas; and
depositing a film from the plasma on the substrate.

20. The method for microwave assisted deposition and etching of claim 19, wherein a cross-section of the containment shield comprises a shape generally corresponding to a circle, a triangle, or a square.

21. The method for microwave assisted deposition and etching of claim 19, wherein the containment shield comprises a dielectric coated metal base connected to a divider comprising at least partially of a dielectric material, the divider being positioned between two adjacent antennas.

22. A method for constructing a containment shield, the method comprising:
shaping a metal base;
applying a dielectric coating on the metal base;
forming a divider, the divider comprising at least partially of a dielectric material and being positioned between antennas for allowing coupling of the antennas;
connecting the divider to the metal base to form a containment shield surrounding the antennas.

23. The method for microwave assisted deposition and etching of claim 22, the metal base comprises aluminum or steel.

24. The method for microwave assisted deposition and etching of claim 22, the dielectric coating comprises Al₂O₃.

25. The method for microwave assisted deposition and etching of claim 22, wherein the divider comprises a dielectric layer and a dielectric coated metal layer disposed over the dielectric layer.
